(19) United States
(12) Patent Application Publication
(10) Pub. No.: US 2025/0273131 A1
(43) Pub. Date: Aug. 28, 2025

(54) DISPLAY DEVICE AND METHOD OF DRIVING SAME

(71) Applicant: LG Display Co., Ltd., Seoul (KR)

(72) Inventors: Ung PARK, Paju-si (KR); Zong Gun OH, Paju-si (KR)

(73) Assignee: LG Display Co., Ltd., Seoul (KR)

(21) Appl. No.: 19/056,220

(22) Filed: Feb. 18, 2025

(30) Foreign Application Priority Data
Feb. 28, 2024 (KR) 10-2024-0028976

(51) Int. Cl. G09G 3/32

(52) U.S. Cl. CPC G09G 3/32; G09G 2310/0275; G09G 2310/0286; G09G 2310/0291; G09G 2310/08; G09G 2330/028

(57) ABSTRACT

Disclosed is a display device including a display panel having a plurality of pixels, a timing controller configured to generate channel control information for each channel on the basis of a resolution of image data to be written to the pixels, and a data driving circuit configured to generate a data voltage corresponding to the image data and output the data voltage to channels connected to the pixels, wherein the data driving circuit sets an enabled channel as a channel to be used and a disabled channel as a channel not to be used for the channels according to the channel control information.

### CROSS-REFERENCE TO RELATED APPLICATION(S)

This application claims the benefit of Korean Patent Application No. 10-2024-0028976, filed on Feb. 28, 2024, which is hereby incorporated by reference as if fully set forth herein.

### BACKGROUND

### Technical Field

The present disclosure relates to a display device and a method of driving the same.

### Description of the Related Art

A display device includes a light-emitting element disposed in each of a plurality of subpixels arranged on a display panel and controls the luminance of each subpixel by controlling the voltage of the light-emitting element to cause the light-emitting element to emit light, thereby displaying an image.

Recently, as the resolutions and sizes of display devices increase, the number of subpixels and the number of data lines for supplying data voltages to the subpixels have increased. In addition, display devices with various resolutions have been produced as display devices have diversified.

### BRIEF SUMMARY

The present disclosure provides a method of effectively controlling channels of source drive integrated circuits (ICs) for supplying data voltages to subpixels. The present disclosure is directed to a display device and a method of driving the same that substantially obviate one or more problems due to limitations and disadvantages of the related art.

The present disclosure is to provide a display device capable of effectively controlling channels of source drive ICs and a method of driving the same.

Additional advantages, objects, and features of the present disclosure will be set forth in part in the description which follows and in part will become apparent to those having ordinary skill in the art upon examination of the following or may be learned from practice of the present disclosure. The objectives and other advantages of the present disclosure may be realized and attained by the structure particularly pointed out in the written description and claims hereof as well as the appended drawings.

As embodied and broadly described herein, a display device includes a display panel having a plurality of pixels, a timing controller configured to generate channel control information for each channel on the basis of a resolution of image data to be written to the pixels, and a data driving circuit configured to generate a data voltage corresponding to the image data and output the data voltage to channels connected to the pixels, wherein the data driving circuit sets an enabled channel as a channel to be used and a disabled channel as a channel not to be used for the channels according to the channel control information.

The data driving circuit may include a shift register configured to sample bits of the image data for each channel and output the sampled bits, a data voltage generation circuit configured to receive the image data from the shift register and generate the data voltage for each channel, a first switch unit configured to set whether the image data is input to the data voltage generation circuit according to the channel control information, and a second switch unit configured to set whether the data voltage output from the data voltage generation circuit is to be output to a relevant channel according to the channel control information.

The data voltage generation circuit may include a plurality of latch circuits configured to convert bits of the image data into a parallel type data system, and a plurality of output amplifiers configured to output a data voltage corresponding to the image data for each channel.

The first switch unit may include a plurality of first switches configured to output an enable signal or a disable signal to each of the plurality of latch circuits according to the channel control information, and the second switch unit may include a plurality of second switches configured to transmit signals output from the plurality of output amplifiers to relevant channels or block the signals according to the channel control information.

The data driving circuit may include a channel control block configured to generate a plurality of first switch signals for respectively controlling operations of the plurality of first switches and a plurality of second switch signals for respectively controlling operations of the plurality of second switches according to the channel control information.

The first switches may include first switch TFTs configured to receive the first switch signals through gate electrodes and apply the enable signal or the disable signal to relevant latches, and the second switches may include second switch TFTs configured to receive the second switch signals through gate electrodes and transmit signals output from the output amplifiers to relevant channels or output the signals to ground.

The timing controller may transmit the channel control information to the data driving circuit during a vertical blank period.

The data driving circuit may include a source drive integrated circuit having a plurality of channels connected to the pixels, and the timing controller may transmit the channel control information to the source drive integrated circuit through an EPI transmission data format.

The EPI transmission data format may include long packet data indicating enable/disable setting information of each of the plurality of channels of the source drive integrated circuit as 1 bit.

In another aspect of the present disclosure, a method of driving a display device includes generating channel control information for each of channels of a data driving circuit on the basis of a resolution of image data to be written to a plurality of pixels included in a display panel, and setting an enabled channel as a channel to be used and a disabled channel as a channel not to be used for the channels according to the channel control information in the data driving circuit.

The data driving circuit may include a shift register configured to sample bits of the image data for each channel and output the sampled bits, a data voltage generation circuit having a plurality of latch circuits configured to receive the image data from the shift register and convert bits of the image data into a parallel type data system, and a plurality of output amplifiers configured to output a data voltage corresponding to the image data for each channel, a first switch unit configured to set whether the image data is input to the data voltage generation circuit according to the channel control information, and a second switch unit configured to set whether the data voltage output from the data voltage generation circuit is to be output to a relevant channel according to the channel control information.

The setting an enabled channel as a channel to be used and a disabled channel as a channel not to be used for the channels according to the channel control information may include outputting, by the first switch unit, an enable signal or a disable signal to each of the plurality of latch circuits according to the channel control information, and transmitting signals output from the plurality of output amplifiers to relevant channels or blocking the signals according to the channel control information, by the second switch unit.

The setting an enabled channel as a channel to be used and a disabled channel as a channel not to be used for the channels according to the channel control information may include setting the enable channel as a channel to be used and the disable channel as a channel not to be used during a vertical blank period.

The data driving circuit may include a source drive integrated circuit having a plurality of channels connected to the pixels, and the channel control information may be transmitted to the source driver integrated circuit through an EPI transmission data format.

It is to be understood that both the foregoing general description and the following detailed description of the present disclosure are exemplary and explanatory and are intended to provide further explanation of the present disclosure including the claims.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate aspect(s) of the present disclosure and together with the description serve to explain the principle of the present disclosure. In the drawings:

FIG. 1 is a diagram showing a display device according to an aspect of the present disclosure;

FIG. 2 is a diagram showing an EPI interface topology for connecting a timing controller and source drive ICs;

FIG. 3 is a diagram showing a connection relationship between a source drive IC and data lines;

FIG. 4 and FIG. 5 are diagrams for describing a method of setting channels of a source drive IC of a display device according to a comparative example;

FIG. 6 is a diagram showing a source drive IC of a display device according to an aspect of the present disclosure;

FIG. 7 is a diagram showing circuit configurations of a first switch unit and a second switch unit in FIG. 6;

FIG. 8 is a diagram for describing a channel setting method of a display device according to an aspect of the present disclosure;

FIG. 9 is a diagram showing an example of an EPI packet configuration in a normal period;

FIG. 10 is a diagram showing an example of an EPI packet configuration in a channel setting period; and

FIG. 11 and FIG. 12 are diagrams showing information included in an EPI packet of FIG. 10.

### DETAILED DESCRIPTION

The advantages and features of the present disclosure and the way of attaining the same will become apparent with reference to aspect s described below in detail in conjunction with the accompanying drawings. The present disclosure, however, is not limited to the aspect s disclosed hereinafter and may be embodied in many different forms. Rather, these exemplary aspect s are provided so that this disclosure will be through and complete and will fully convey the scope to those skilled in the art.

The shapes, sizes, ratios, angles, numbers, and the like, which are illustrated in the drawings in order to describe various aspects of the present disclosure, are merely given by way of example, and therefore, the present disclosure is not limited to the illustrations in the drawings. The same or extremely similar elements are designated by the same reference numerals throughout the specification. In the present specification, when the terms “comprise,” “include,” and the like are used, other elements may be added unless the term “only” is used. An element described in the singular form is intended to include a plurality of elements unless the context clearly indicates otherwise.

In the interpretation of constituent elements included in the various aspects of the present disclosure, the constituent elements are interpreted as including an error range even if there is no explicit description thereof.

In the description of the various aspects of the present disclosure, when describing positional relationships, for example, when the positional relationship between two parts is described using “on,” “above,” “below,” “beside,” or the like, one or more other parts may be located between the two parts unless the term “directly” or “closely” is used.

Although terms such as, for example, “first” and “second” may be used to describe various elements, these terms are merely used to distinguish the same or similar elements from each other. Therefore, in the present specification, an element modified by “first” may be the same as an element modified by “second” within the technical scope of the present disclosure unless mentioned otherwise.

Throughout the specification, the same reference numerals refer to substantially the same components. Hereinafter, aspect s of the present disclosure will be described in detail with reference to the accompanying drawings. In the following description, when it is determined that detailed description of a known function or configuration related to the present disclosure may unnecessarily obscure the subject matter of the present disclosure, the detailed description will be omitted.

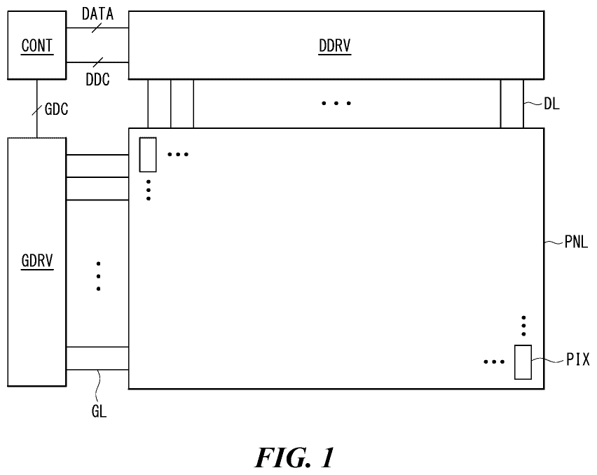

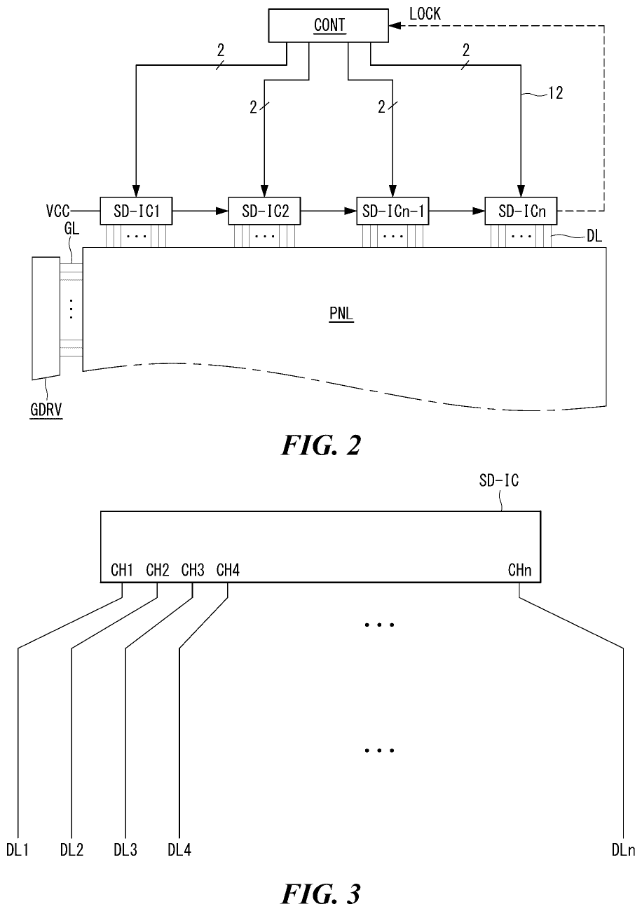

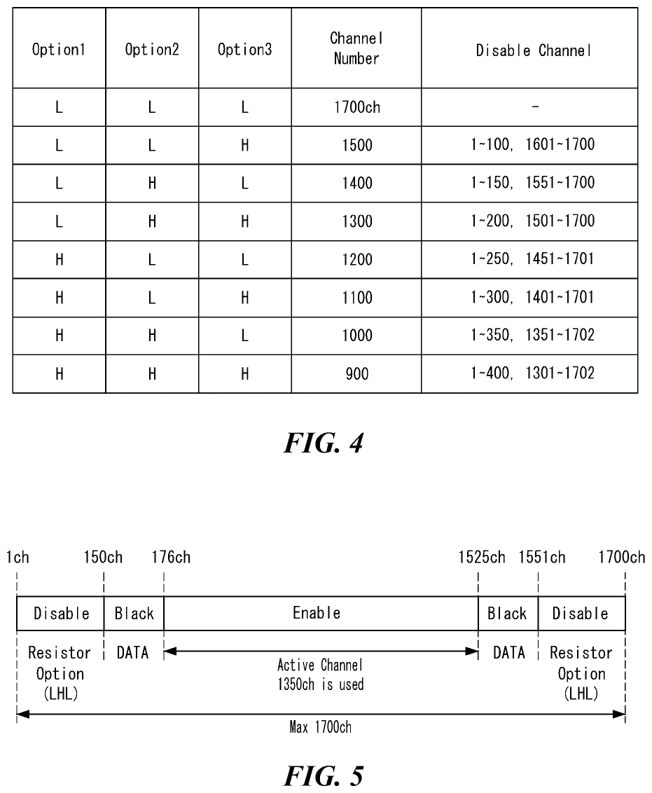

FIG. 1 is a diagram showing a display device according to an aspect of the present disclosure. FIG. 2 is a diagram showing an EPI interface topology for connecting a timing controller and SD-ICs. FIG. 3 is a diagram showing a connection relationship between an SD-IC and data lines. Further, FIG. 2 is a diagram showing a connection relationship between a source drive IC and data lines in a display device according to an aspect of the present disclosure.

Referring to FIG. 1, a display device according to an aspect of the present disclosure may be implemented as an electroluminescent display device or a liquid crystal display device including a display panel PNL, a timing controller CONT, a data driving circuit DDRV, and a gate driving circuit GDRV.

The display panel PNL includes a plurality of data lines DL and a plurality of gate lines GL, and pixels PIX may be disposed at intersections of these signal lines GL and DL. A pixel array can be formed by the pixels PIX arranged in a matrix form in a display area of the display panel PNL.

In the pixel array, pixels PIX are adjacent to each other in the horizontal direction to form horizontal lines. The number of horizontal lines is a vertical resolution of the display panel PNL. Pixels PIX forming the same horizontal line are connected to the same gate line GL and are connected to different data lines DL. Each pixel PIX may be implemented as a light-emitting cell including a light-emitting diode or a liquid crystal cell including a liquid crystal layer.

The gate driving circuit GDRV generates a scan signal SCAN on the basis of a gate timing control signal GDC from a timing controller CONT and supplies the scan signal SCAN to the gate lines GL. A horizontal line to which a data voltage will be written is selected by the scan signal SCAN. The gate driving circuit GDRV may be embedded in a non-display area of the display panel PNL according to a gate-in-panel GIP) structure. The non-display area may be located outside the panel array in the display panel PNL.

The data driving circuit DDRV may include at least one source drive IC SD-IC. The data driving circuit DDRV supplies a data voltage to the data lines DL. A pixel data voltage is supplied to the data lines DL and applied to the pixels PIX through a switch element. The data driving circuit DDRV may be implemented using one or more source drive ICs SIC1 to SICn as shown in FIG. 2.

The timing controller CONT may generate a data timing control signal DDC for controlling the operation timing of the data driving circuit DDRV and a gate timing control signal GDC for controlling the operation timing of the gate driving circuit GDRV on the basis of timing signals such as a vertical synchronization signal Vsync, a horizontal synchronization signal Hsync, and a data enable signal DE input from a host system (not shown). The gate timing control signal GDC may include a gate start signal, a gate shift clock signal, etc. The data timing control signal DDC may include a source start pulse, a source sampling clock signal, a source output enable signal, etc.

The timing controller CONT transmits image data DATA input from the host system to the data driving circuit DDRV through an internal interface circuit. The image data DATA is for image display in pixels PIX, and is converted into a data voltage in the data driving circuit DDRV and then written to pixels PIX. The internal interface circuit may be an embedded panel interface (EPI) circuit.

The timing controller CONT may configure the timing control signal DDC, output control information, and the image data DATA into an EPI packet, which is EPI transmission format data, and then transmit the EPI packet to the data driving circuit DDRV.

As shown in FIG. 2, the EPI interface can reduce the number of interconnection lines between the timing controller CONT and the source drive ICs SIC1 to SICn by connecting the timing controller CONT and the source drive ICs SIC1 to SICn in a point-to-point manner. In the EPI interface, an EPI signal including control data and pixel data having embedded clocks are transmitted through data line pairs 12, and thus separate clock lines and control lines are not required. The data line pairs 12 are separated by source drive ICs and thus the timing controller CONT can be connected to the source drive ICs SIC1 to SICn.

Each of the source drive ICs SIC1 to SICn separates the data timing control signal DDC, output control information, and image data DATA from the EPI packet received from the timing controller CONT via the data line pairs 12. When the phase and frequency of an internal clock signal CDR CLK are locked, the source drive ICs SIC1 to SICn feed back a lock signal LOCK at a high logic level, which indicates an output stable state, to the timing controller CONT. A high logic level DC power supply voltage VCC is input to a lock signal input terminal of the first source drive IC SIC1. The lock signal LOCK is fed back to the timing controller CONT by the last source drive IC SD-ICn.

The source drive ICs SIC1 to SICn may output analog data signals to each of the data lines DL1 to DLn according to a source output enable signal SOE included in the data timing control signal DDC. As illustrated in FIG. 3, the source drive ICs SIC1 to SICn convert image data DATA into a data voltage on the basis of the data timing control signal DDC, and then supply the data voltage to the data lines DL1 to DLn through data output channels CH1 to CHn.

To achieve various resolutions in the display device having the aforementioned configuration, only some of the output channels CH1 to CHn of the source drive ICs SIC1 to SICn may be used to output a data voltage.

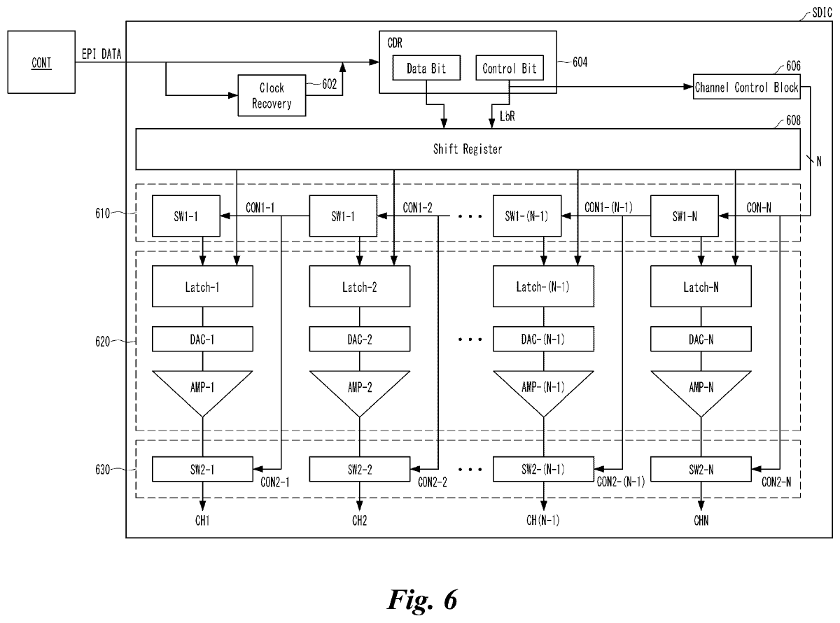

FIG. 4 and FIG. 5 are diagrams for describing a method of setting channels of a source drive integrated circuit of a display device according to a comparative example. FIG. 4 is a table showing channel setting information of a source drive IC SD-IC, and FIG. 5 is a diagram illustrating channels set according to the table of FIG. 4.

In the display device according to the comparative example, a resistor option is set during channel setting to disable a specific channel group, and black data is transmitted for detailed channel setting to achieve a desired resolution.

Referring to FIG. 4, Option1, Option2, and Option3 can be set as resistor options, and a specific channel group can be disabled by setting each option to low (L) or high (H). Accordingly, a total of eight channels can be set with LHL combinations.

When the total number of channels is 1700ch, Option1, Option2, and Option3 can all be set to L to enable all channels.

For example, if Option1, Option2, and Option3 are set to LHH, 1 to 200ch and 1501 to 1700ch are disabled. Accordingly, 1300 channels of 201 to 1500ch can be enabled and used.

For example, if Option1, Option2, and Option3 are set to HLH, 1 to 300ch and 1401 to 1701ch are disabled. Accordingly, 1100 channels of 301 to 1400ch can be enabled and used.

FIG. 5 shows an example of a channel status when 1350 channels among a total of 1700 channels are enabled and used.

If 1350 channels are desired to be set, resistor options are set to “LHL” as shown in FIG. 4 to enable 1400 channels. If Option1, Option2, and Option3 are set to LHL, 1 to 150ch and 1511 to 1700ch are disabled. Accordingly, 1400 channels of 151 to 1510ch can be enabled and used.

Among 1400 channels of 151 to 1510ch selected by the resistor options, 50 channels at the start and end points may be set to dummy channels by setting data black therefor, thereby setting 1350ch to be enable channels. A dummy channel can set a start channel point based on a minimum number of channels required for 1 format, according to the RGB data format. For example, as shown in FIG. 5, by setting 151 to 175 channels as data black at the start point and setting 1526 to 1550 channels as data black at the end point, a total of 1350 channels from 176ch to 1525ch can be used as enable channels.

As described above, the display device according to the comparative example can set the resolution for each source drive IC SD-IC by combining resistor options and data black setting. Therefore, resistors are required according to resistor option setting, and a disable channel can be selected only by eight setting methods selectable by resistor options, and thus there is a limitation in selecting a start point of source output. In addition, a dummy channel set to data black is not connected to a data line, but is black data included in the horizontal resolution, and thus it affects a data transmission rate. Further, as the black data section increases, the data transmission timing margin may be insufficient.

Therefore, a display device according to aspect s of the present disclosure freely sets source output channels by using an EPI packet without using resistors or the like.

In a display device according to an aspect of the present disclosure, a timing controller CONT may configure control data and image data DATA as EPI data EPI DATA in the form of packet data and transmit the same to source drive ICs SIC1 to SICn. The timing controller CONT may determine an enabled channel and a disabled channel according to a resolution to be achieved, include channel setting information in control information Control, and output the control information including the channel setting information.

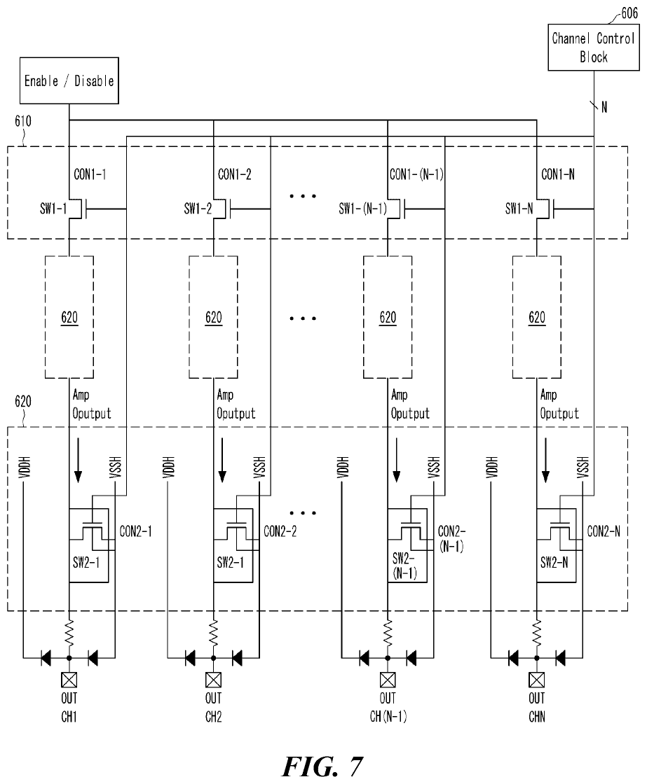

FIG. 6 is a diagram showing a source drive IC SD-IC of a display device according to an aspect of the present disclosure.

Referring to FIG. 6, the source drive IC SD-IC may include a clock recovery unit 602, a clock and data recovery unit (CDR) 604, a channel control block 606, a shift register 608, a first switch unit 610, a data voltage generation circuit 620, and a second switch unit 630.

The clock recovery unit 602 restores a clock signal according to a clock training pattern and a clock signal included in EPI data to generate an internal clock signal.

The CDR 604 samples control bits and image data bits from the EPI data in accordance with internal clock timing.

The control bits may include output control information for controlling data output and channel control information for controlling the first switch unit 610 and the second switch unit 630. The data output control information may include an SOE signal and the like. The channel control information may include information on setting of enabled and disabled channels among output channels CH1 to CHN of the source drive IC SD-IC.

The CDR 604 transmits the output control information among the control bits to the data voltage generation circuit 620 through the shift register 608 along with the image data bits. The CDR 604 transmits the channel control information among the control bits to the channel control block 606.

The channel control block 606 independently sets channel control signals CON1-1 to CON1-N and CON2-1 to CON2-N for data output channels according to the channel control information. Among the channel control signals CON1-1 to CON1-N and CON2-1 to CON2-N, the first channel control signals CON1-1 to CON1-N are applied to the first switch unit 610, and the second channel control signals CON2-1 to CON2-N are applied to the second switch unit 630 such that the channels can be enabled or disabled independently.

The data voltage generation circuit 620 may receive the output control information and image data bits through the shift register 608, generate an image data voltage, and output the same to the output channels CH1 to CHN. The data voltage generation circuit 620 may include N latch circuits Latch-1 to Latch-N, N D/A conversion circuits DACI to DAC-N, and N output amplifiers AMP-1 to AMP-N connected to N signal lines from the shift register 608.

The latch circuits Latch-1 to Latch-N convert sampled image data bits transmitted through the shift register 608 into a parallel type data system.

The D/A conversion circuits DAC-1 to DAC-N convert image data converted into a parallel type data system into a gamma compensation voltage to generate data voltages.

The output amplifiers AMP-1 to AMP-N output a target data voltage corresponding to the image data to the data output channels CH1 to CHN.

The data voltage generation circuit 620 may apply the image data voltage generated for each channel using the aforementioned configuration to each data line DL connected to the output channels CH1 to CHN.

The first switch unit 610 and the second switch unit 630 may selectively transmit or block a signal input to the data voltage generation circuit 620 and a signal output therefrom according to the first channel control signals CON1-1 to CON1-N and the second channel control signals CON2-1 to CON2-N, respectively. Accordingly, it is possible to enable or disable a specific output channel by controlling the first switch unit 610 and the second switch unit 630 using the first channel control signals CON1-1 to CON1-N and the second channel control signals CON2-1 to CON2-N.

The first switch unit 610 may control the output control information and image data bits transmitted from the shift register 608 to be received by the data voltage generation circuit 620 or blocked according to the first channel control signals CON1-1 to CON1-N. The first switch unit 610 includes N first switches SW1-1 to SW1-N corresponding to the N latch circuits Latch-1 to Latch-N of the data voltage generation circuit 620, which can operate independently according to the first channel control signals CON1-1 to CON1-N. The first switch unit 610 may enable/disable the latch circuits Latch-1 to Latch-N of the data voltage generation circuit 620 according to the first channel control signals CON1-1 to CON1-N. A latch circuit enabled by the first switch unit 610 may perform a series of processes of receiving the output control information and image data bits and generating an image data voltage. A disabled latch circuit switches to a disabled state and stops receiving data. Therefore, each channel can be independently enabled/disabled using the first channel control signals CON1-1 to CON1-N.

The second switch unit 630 may control the data voltage generated by the data voltage generation circuit 620 to be output or blocked according to the second channel control signals CON2-1 to CON2-N. The second switch unit 630 includes second switches SW1-1 to SW1-N connected to N signal lines from the output amplifiers AMP-1 to AMP-N to the channels CH1 to CHN connected to the data lines of the panel, which can operate independently according to the second channel control signals CON2-1 to CON2-N. The second switch unit 630 may transmit or block the output of the output amplifiers AMP-1 to AMP-N of the data voltage generation circuit 620 according to the second channel control signals CON2-1 to CON2-N. The data voltages of the output amplifiers AMP-1 to AMP-N connected by the second switch unit 630 can be supplied to the data lines of the panel through the corresponding channels CH1 to CHN. Therefore, each channel can be independently enabled/disabled using the second channel control signals CON2-1 to CON2-N.

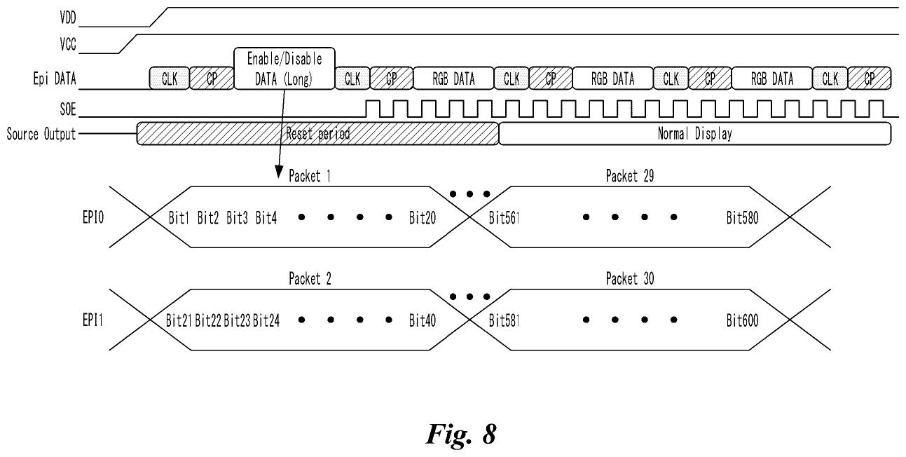

FIG. 7 is a diagram showing circuit configurations of the first switch unit 610 and the second switch unit 630 in FIG. 6.

Referring to FIG. 7, the first switch unit 610 and the second switch unit 630 may operate by receiving the first channel control signals CON1-1 to CON1-N and the second channel control signals CON2-1 to CON2-N input through a common node. That is, the same channel control signal may be input to a first switch and a second switch for controlling the same channel. Accordingly, the first switch and the second switch for controlling the same channel may operate in association with each other to enable or disable the corresponding channel.

The first switch unit 610 may include N first switches SW1-1 to SW1-N that are turned on/off by the first channel control signals CON1-1 to CON1-N and apply an enable/disable signal to each of the latch circuits Latch-1 to Latch-N of the data voltage generation circuit 620. These first switches SW1-1 to SW1-N may be implemented as switch TFTs that are turned on/off by receiving the first channel control signals CON1-1 to CON1-N through gate electrodes and transmit an enable/disable signal to the latch circuits Latch-1 to Latch-N.

The second switch unit 630 may include second switches SW2-1 to SW2-N which are controlled to be turned on/off by the second channel control signals CON2-1 to CON2-N and connected to N signal lines through which signals are supplied from the output amplifiers AMP-1 to AMP-N to the channels CH1 to CHN connected to the data lines of the panel. The second switch unit 630 may transmit or block the output of the output amplifiers AMP-1 to AMP-N of the data voltage generation circuit 620 according to the second channel control signals CON2-1 to CON2-N. These second switches SW2-1 to SW2-N may be implemented as switch TFTs that receive the second channel control signals CON2-1 to CON2-N through gate electrodes and transmit the output of the output amplifiers AMP-1 to AMP-N to the corresponding channels CH1 to CHN or block the same. The second switches SW2-1 to SW2-N operate in association with the first switches SW1-1 to SW1-N that control the same channel, and thus they block the output of the output amplifier of the corresponding channel to prevent unintended data (unknown data) from being output when the latch circuit of the corresponding channel is in a disabled state. The second switches SW2-1 to SW2-N may form a GND path such that the output of the output amplifier is connected to the ground GND in order to block the output of the output amplifier.

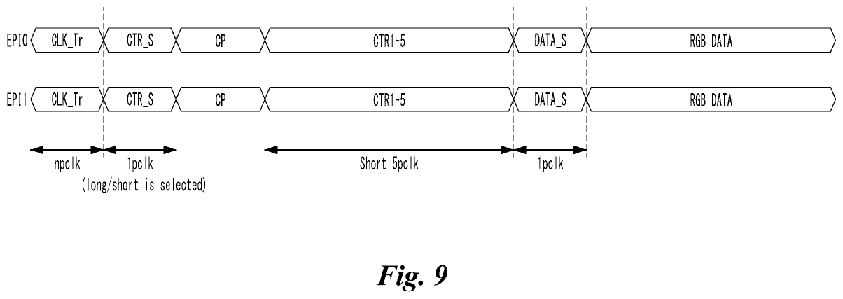

FIG. 8 is a diagram for describing a channel setting method of a display device according to an aspect of the present disclosure.

The display device according to the aspect of the present disclosure can freely set a source output channel using an EPI packet. In the display device according to the aspect of the present disclosure, the timing controller CONT may configure control data and image data as EPI data in the form of packet data and transmit the same to the source drive ICs SIC1 to SICn. The timing controller CONT may determine an enabled channel and a disabled channel according to a resolution to be achieved and output, include channel setting information in control information, and output the control information including the channel setting information.

Referring to FIG. 8, a channel setting process may be performed during Turn-On and vertical blank (V-Blank) periods in the display device. In the vertical blank period, which is a source output reset period, channel setting information (Enable/Disable DATA) of the source drive ICs SIC1 to SICn may be transmitted as long packet data. After channel setting of the source drive ICs SIC1 to SICn is completed, display data may be transmitted such that the display device can operate in a normal display mode.

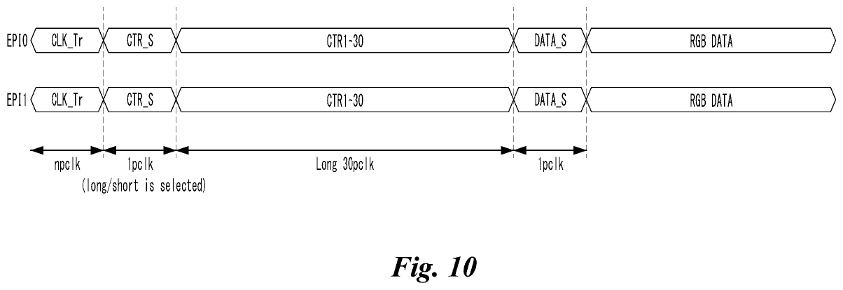

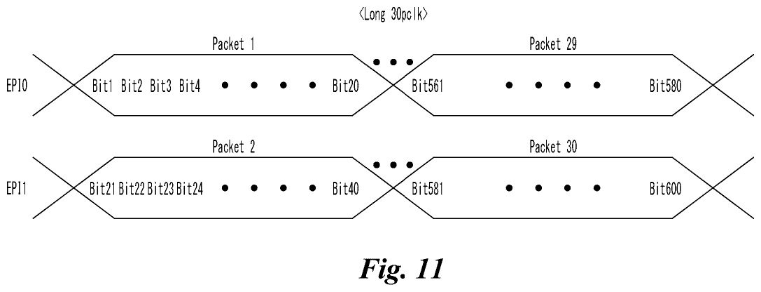

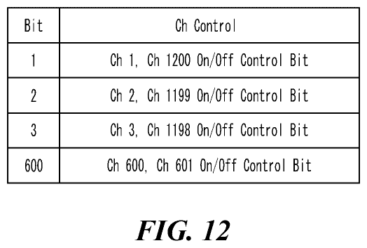

The EPI data used for channel setting will be described with reference to FIG. 9 to FIG. 12. FIG. 9 is a diagram illustrating an EPI data configuration in a normal period, and FIG. 10 is a diagram illustrating an EPI data configuration in a channel setting period. FIG. 11 and FIG. 12 are diagrams illustrating information included in the EPI data of FIG. 10. An example in which the EPI packet illustrated below operates in 2 pairs will be described.

FIG. 9 is a diagram illustrating an EPI data configuration in a normal period, which can be used when display data is transmitted after channel setting is completed.

Referring to FIG. 9, EPI data of a normal period may be composed of short packets. The EPI data composed of short packets may include n packets CLK_Tr for clock training, a control start packet CTR_S storing long packet or short packet setting information, a control packet CP in which timing control information such as an SOE signal is set, control packets CTR1 to CTR5 for transmitting simple setting information, a data start packet DATA_S, and an image data (RGB DATA) packet. Since the EPI data composed of short packets in a normal period is transmitted after channel setting is completed, separate channel setting information may not be included therein.

FIG. 10 is a diagram illustrating an EPI data configuration in a channel setting period. The EPI data in a channel setting period is transmitted in a vertical blank period and may be composed of long packets. Referring to FIG. 10, the EPI data composed of long packets may include n packets CLK_Tr for clock training, a control start packet CTR_S storing long packet or short packet setting information, control packets CTR1 to CTR30 for channel setting, a data start packet DATA_S, and an image data (RGB DATA) packet. Here, the number or the configuration method of 30 packets CTR1 to CTR30, which are long packets for channel setting, may be changed in various manners depending on the system.

FIG. 11 and FIG. 12 are diagrams illustrating information included in the EPI data of FIG. 10. FIG. 11 illustrates channel information included in control packets CTR1 to CTR30 for channel setting, and FIG. 12 is a table showing a channel setting method.

Referring to FIG. 11 and FIG. 12, 20-bit information may be included per packet of the control packets CTR1 to CTR30. Accordingly, 600 bits can be set for EPI0 and 600 bits can be set for EPI1, and thus a total of 1200 bits of information can be set. Accordingly, if one channel is allocated per bit, the channel is disabled (Latch (SW1)/AMP (SW2) is turned off) in the case of “0” bit, and the channel is enabled (Latch (SW1)/AMP (SW2) is turned on) in the case of “1” bit, a total of 1200 channels can be enabled/disabled. That is, as shown in the table of FIG. 12, Bit1 of EPI0 may be set to channel 1, Bit1 of EPI1 may be set to channel 1200, Bit600 of EPI0 may be set to channel 600, Bit600 of EPI1 may be set to channel 601, a channel to be used may be set to “1,” and a channel not to be used may be set to “0.”

As described above, the aspect of the present disclosure includes the first switch unit for enabling/disabling the latches of the source drive IC and the second switch unit for enabling/disabling the output of the output amplifiers, and sets the operation of each switch to a long packet of EPI data to set a channel to be used and a channel not to be used during a V blank period, thereby easily setting output channels only with EPI data without using existing resistors. Accordingly, the channels of the source drive IC can be enabled/disabled independently, thereby improving the degree of freedom in channel setting of the display device. In addition, the aspect of the present disclosure can enable/disable channels independently without using a resistor for channel setting in a conventional display device, thereby eliminating the configuration of conventional resistors and consequently eliminating pins for resistor options, resulting in a reduction in the number of input pins of the source drive ICs. Furthermore, the aspect of the present disclosure can enable/disable channels independently without dummy black data for channel setting in a conventional display device, thereby securing a data timing margin equivalent to dummy black data in one piece of horizontal data.

Aspects of the present disclosure have the following advantages.

The aspect s of the present disclosure can improve the degree of freedom in channel setting of a display device by enabling/disabling channels of a source drive IC for each channel.

The aspect s of the present disclosure can enable/disable channels independently without using a resistor required for channel setting in a conventional display device, thereby eliminating the configuration of conventional resistors and consequently eliminating pins for resistor options, thereby reducing the number of input pins of a source drive IC.

The aspect s of the present disclosure can enable/disable channels independently without dummy black data required for channel setting in a conventional display device, thereby securing a data timing margin equivalent to dummy black data in one piece of horizontal data.

The effects according to the present disclosure are not limited to the above description, and more diverse effects are included in the present disclosure.

It will be apparent to those skilled in the art that various modifications and variations can be made in the present disclosure without departing from the spirit or scope of the present disclosure. Thus, it is intended that the present disclosure covers the modifications and variations of the present disclosure including the appended claims and their equivalents.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel having a plurality of pixels;
a timing controller configured to generate channel control information for each channel on the basis of a resolution of image data to be written to the pixels; and
a data driving circuit configured to generate a data voltage corresponding to the image data and output the data voltage to channels connected to the pixels,
wherein the data driving circuit is configured to set an enabled channel as a channel to be used and a disabled channel as a channel not to be used for the channels based on the channel control information.

2. The display device of claim 1, wherein the data driving circuit comprises:
a shift register configured to sample bits of the image data for each channel and output the sampled bits;
a data voltage generation circuit configured to receive the image data from the shift register and generate the data voltage for each channel;
a first switch unit configured to set whether the image data is input to the data voltage generation circuit according to the channel control information; and
a second switch unit configured to set whether the data voltage output from the data voltage generation circuit is to be output to a relevant channel according to the channel control information.

3. The display device of claim 2, wherein the data voltage generation circuit comprises:
a plurality of latch circuits configured to convert bits of the image data into a parallel type data system; and
a plurality of output amplifiers configured to output a data voltage corresponding to the image data for each channel.

4. The display device of claim 3, wherein the first switch unit comprises a plurality of first switches configured to output an enable signal or a disable signal to each of the plurality of latch circuits based on the channel control information, and the second switch unit comprises a plurality of second switches configured to transmit signals output from the plurality of output amplifiers to relevant channels or block the signals based on the channel control information.

5. The display device of claim 4, wherein the data driving circuit comprises a channel control block configured to generate a plurality of first switch signals for respectively controlling operations of the plurality of first switches and a plurality of second switch signals for respectively controlling operations of the plurality of second switches based on the channel control information.

6. The display device of claim 5, wherein the first switches comprise first switch TFTs configured to receive the first switch signals through gate electrodes and apply the enable signal or the disable signal to relevant latches, and the second switches comprise second switch TFTs configured to receive the second switch signals through gate electrodes and transmit signals output from the output amplifiers to relevant channels or output the signals to ground.

7. The display device of claim 1, wherein the timing controller is configured to transmit the channel control information to the data driving circuit during a vertical blank period.

8. The display device of claim 1, wherein the data driving circuit comprises a source drive integrated circuit having a plurality of channels connected to the pixels, and the timing controller is configured to transmit the channel control information to the source drive integrated circuit through an EPI transmission data format.

9. The display device of claim 8, wherein the EPI transmission data format includes long packet data indicating enable or disable setting information of each of the plurality of channels of the source drive integrated circuit as 1 bit.

10. A method of driving a display device, comprising:
generating channel control information for each of channels of a data driving circuit on the basis of a resolution of image data to be written to a plurality of pixels included in a display panel; and
setting an enabled channel as a channel to be used and a disabled channel as a channel not to be used for the channels according to the channel control information in the data driving circuit.

11. The method of claim 10, wherein the data driving circuit comprises:
a shift register configured to sample bits of the image data for each channel and output the sampled bits;
a data voltage generation circuit having a plurality of latch circuits configured to receive the image data from the shift register and convert bits of the image data into a parallel type data system, and a plurality of output amplifiers configured to output a data voltage corresponding to the image data for each channel;
a first switch unit configured to set whether the image data is input to the data voltage generation circuit based on the channel control information; and
a second switch unit configured to set whether the data voltage output from the data voltage generation circuit is to be output to a relevant channel based on the channel control information.

12. The method of claim 11, wherein the setting an enabled channel as a channel to be used and a disabled channel as a channel not to be used for the channels according to the channel control information comprises:
outputting, by the first switch unit, an enable signal or a disable signal to each of the plurality of latch circuits based on the channel control information; and
transmitting signals output from the plurality of output amplifiers to relevant channels or blocking the signals based on the channel control information, by the second switch unit.

13. The method of claim 10, wherein the setting an enabled channel as a channel to be used and a disabled channel as a channel not to be used for the channels according to the channel control information comprises setting the enable channel as a channel to be used and the disable channel as a channel not to be used during a vertical blank period.

14. The method of claim 10, wherein the data driving circuit comprises a source drive integrated circuit having a plurality of channels connected to the pixels, and the channel control information is transmitted to the source driver integrated circuit through an EPI transmission data format.
